(19) United States
(12) Patent Application Publication
(10) Pub. No.: US 2013/0168132 A1
(43) Pub. Date: Jul. 4, 2013

(54) PRINTED CIRCUIT BOARD AND METHOD OF MANUFACTURING THE SAME

(71) Applicant: SUMSUNG ELECTRO-MECHANICS CO., LTD., Suwon (KR)

(72) Inventors: Chang Bae Lee, Suwon (KR); Jin Gu Kim, Suwon (KR); Young Do Kweon, Suwon (KR)

(73) Assignee: SUMSUNG ELECTRO-MECHANICS CO., LTD., Suwon (KR)

(21) Appl. No.: 13/729,666

(22) Filed: Dec. 28, 2012

(30) Foreign Application Priority Data
Dec. 29, 2011 (KR) 10-2011-0146073
Dec. 24, 2012 (KR) 10-2012-0152427

(51) Int. Cl. H05K 3/00; H05K 1/11

(52) U.S. Cl. CPC H05K 3/00; H05K 1/111
USPC 174/250; 216/13

(57) ABSTRACT

Disclosed herein are a printed circuit board and a method of manufacturing the same. The printed circuit board includes a base substrate; a circuit layer including a connection pad having a vertically etched upper portion and formed on the upper portion of the base substrate; a solder resist layer formed on the upper portion of the base substrate and including an opening part exposing the connection pad; and a surface treatment layer formed on the upper portion of the connection pad exposed by the opening part.

### CROSS REFERENCE TO RELATED APPLICATION

This application claims the benefit of Korean Patent Application No. 10-2011-0146073, filed on Dec. 29, 2011, entitled “Printed circuit Board and Manufacturing Method of Printed circuit Board”, Korean Patent Application No. 10-2012-0152427, filed Dec. 24, 2012, entitled “Printed circuit Board and Method of Manufacturing the Same”, which are hereby incorporated by reference in its entirety into this application.

### BACKGROUND OF THE INVENTION

1. Technical Field

The present invention relates to a printed circuit board and a method of manufacturing the same.

2. Description of the Related Art

Recently, the trend of multifunctional and high-speed electronic products has progressed at a rapid speed. In order to meet the trend, a technology connecting an external device such as a semiconductor chip to a printed circuit board has been rapidly developed.

A high-speed and a high integration of the printed circuit board are requested for developing the printed circuit board for mounting the external device thereon. In addition, in order to meet the requirements, the printed circuit board mounting the external device thereon is requested to be improved and developed, that is, to be light and slim, and have a fine circuit, excellent electrical characteristics, high reliability, high-speed signal transfer structure, or the like.

In order to mount the external device on the printed circuit board, a connection pad for mounting the external apparatus and a solder resist layer for exposing an upper portion of the connection pad may be formed on an outermost layer of the printed circuit board. A bump may be formed on the exposed connection pad, the external device may be mounted on the printed circuit board and be electrically connected with each other by the bump.

However, a surface oxide film on the upper portion of the connection pad may be removed by a wet etching process before the bump is formed on the exposed connection pad. During the wet etching process, the connection pad is excessively etched by a depth of 1 um or more, whereby an undercut phenomenon occurs. In addition, at the time of mounting the solder bump, the connection pad may be finally reacted by a depth of 2 to 3 um by dissolution and diffusion reactions of the connection pad. Therefore, the solder bump is reacted with the mounted connection pad and even with the connection pad in a lower portion of the solder resist layer, whereby the bump may separated from the connection pad.

### SUMMARY OF THE INVENTION

The present invention has been made in an effort to provide a printed circuit board capable of preventing an undercut at the time of removal of a surface oxide film of a connection pad, and a method of manufacturing the same.

Further, the present invention has been made in an effort to provide a printed circuit board capable of improving connection reliability between a connection pad and a solder bump, and a method of manufacturing the same.

Further, the present invention has been made in an effort to provide a printed circuit board capable of reducing a cost and time by omitting unit process of a surface treatment process, and a method of manufacturing the same.

According to a preferred embodiment of the present invention, there is provided a printed circuit board including: a base substrate; a circuit layer including a connection pad having a vertically etched upper portion and formed on the upper portion of the base substrate; a solder resist layer formed on the upper portion of the base substrate and including an opening part exposing the connection pad; and a surface treatment layer formed on the upper portion of the connection pad exposed by the opening part.

The connection pad may have an upper portion exposed by the opening part and vertically etched by a depth of 0.1 um or less.

The surface treatment layer may be formed of an organic solderability preservative (OSP).

The OSP may be formed of at least one of imidazoles, benzotriazoles and benzimidazoles.

The surface treatment layer is formed of the metal surface treatment layer.

The metal surface treatment layer is formed of at least one of ENEPIG (Electroless nickel-electroless palladium-immersion gold) and ENIG (Electroless nickel-immersion gold).

The printed circuit board may further include a solder bump formed on the upper portion of the surface treatment layer.

According to another preferred embodiment of the present invention, there is provided a method of manufacturing a printed circuit board, including: preparing a base substrate having a circuit layer formed thereon, the circuit layer including a connection pad exposed to the outside; performing a plasma etching process on the upper portion of the connection pad; and forming a surface treatment layer on the upper portion of the connection pad subjected to the plasma etching process.

In the performing of the plasma etching process, a reactive gas may be an argon (Ar) gas, a hydrogen (H2) gas or a mixture gas of argon and hydrogen.

In the performing of the plasma etching process, the connection pad of the base substrate may be removed by a depth of 0.1 um or less.

In the forming of the surface treatment layer, the surface treatment layer may be formed of an OSP.

The OSP may be formed of at least one of imidazoles, benzotriazoles and benzimidazoles.

In the forming of the surface treatment layer, the surface treatment layer may be formed of the metal surface treatment layer.

The metal surface treatment layer mat be formed of at least one of ENEPIG (Electroless nickel-electroless palladium-immersion gold) and ENIG (Electroless nickel-immersion gold).

The method may further include performing a degreasing process on the base substrate before the performing of the plasma etching process.

The method may further include performing a washing process on the base substrate after the performing of the degreasing process.

The method may further include performing a washing process on the base substrate after the forming of the surface treatment layer.

The method may further include performing a drying process on the base substrate after the performing of the washing process.

The method may further include forming a solder bump on the upper portion of the surface treatment layer after the forming of the surface treatment layer.

### BRIEF DESCRIPTION OF THE DRAWINGS

FIG. 1 is a view showing a printed circuit board according to a preferred embodiment of the present invention; and

FIGS. 2 to 12 are views sequentially showing a method of manufacturing a printed circuit board according to the preferred embodiments of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings.

Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Hereinafter, a printed circuit board and a method of manufacturing the same according to preferred embodiments of the present invention will be described in detail with reference to the accompanying drawings.

Printed Circuit Board

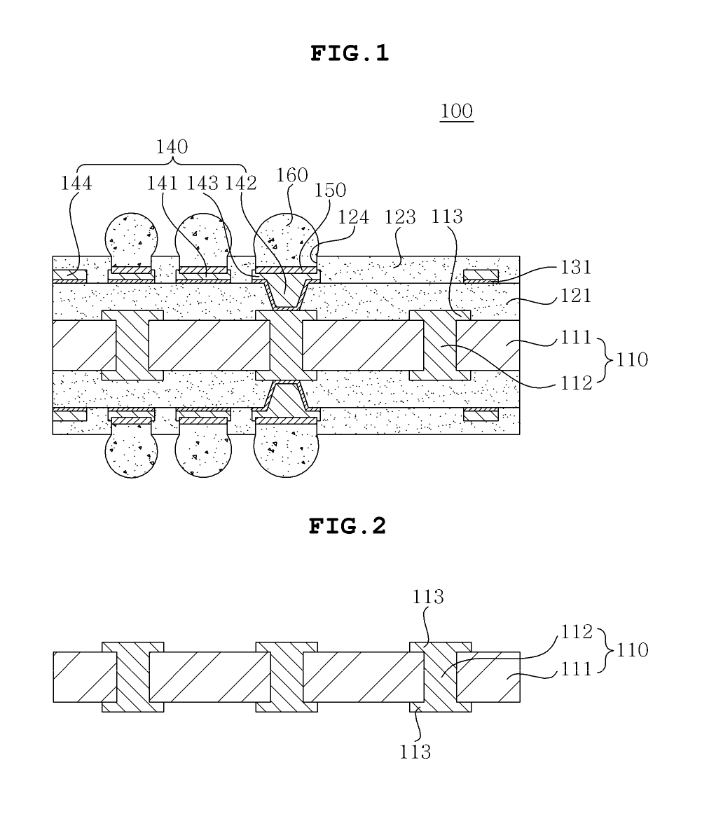

FIG. 1 is a view showing a printed circuit board according to a preferred embodiment of the present invention.

Referring to FIG. 1, the printed circuit board 100 may be configured to include a base substrate 110, a first circuit layer 113, a first insulating layer 121, a second circuit layer 140, a solder resist layer 123, a surface treatment layer 150 and a solder bump 160.

The base substrate 110 may be formed of a hard material capable of supporting a printed circuit board to be built-up. For example, the base substrate 110 may be formed of a metal plate or an insulating material. Here, the metal plate may be a copper foil, and the insulating material may be a complex polymer resin. Alternatively, the base substrate 110 may easily implement a fine circuit by adopting an Ajinomoto build up film (ABF) or manufacture a printed circuit board to be thin by adopting prepreg. However, the base substrate 110 is not limited thereto, but the base substrate 110 may be formed of a hard insulating material including, an epoxy resin or a modified epoxy resin, a bisphenol A resin, an epoxy-novolak resin, or an aramid reinforced or glass fiber reinforced or paper reinforced epoxy resin. The base substrate 110 according to the preferred embodiment of the present invention may be a double-sided metallic laminate plate 111 having copper foils formed on both sided of the insulating material.

In addition, the base substrate 110 may include a through via 112. When first circuit layers 113, which are inner circuit layers, are formed on both sides of the base substrate 110, the through via 112 may be formed in order to electrically interconnect the first circuit layers 113. The through via 112 may be formed of a conductive metal.

The first circuit layer 113 may be formed on an upper portion of the base substrate 110. As shown in FIG. 1, the first circuit layer 113 may be formed on the upper portions of both sides of the base substrate 110, respectively. The first circuit layer 113 formed on both sides of the base substrate 110 may be electrically interconnected by the through via 112. The first circuit layer 113 may be formed of a conductive metal. For example, the first circuit layer 113 may be formed of at least one of gold, silver, nickel, aluminum, copper, and an alloy thereof.

The first insulating layer 121 may be formed on upper portions of the base subs cite 110 and the first circuit layer 113. The first insulating layer 121 may include the via hole 122 exposing the first circuit layer 113. Here, the first insulating layer 121 may be an insulating layer generally used. That is, as a material of the first circuit layer 121, an epoxy based resin such as FR-4, BT, ABF, or the like may be used.

The second circuit layer 140 may be formed on an upper portion of the first insulating layer 121. The second circuit layer 140 may include a connection pad 141, a via 142, a via pad 143, a second circuit pattern 144 or the like. Here, a second circuit pattern 144 is general circuit pattern for electric signal transmission. The connection pad 141 and the via pad 143 may be a constitution part for electrically interconnecting the second circuit layer 140 and structures formed on the upper portion of the second circuit layer 140. According to the preferred embodiment of the present invention, the via pad 143 may be formed on the upper portion of the via 142. In addition, The connection pad 141 and the via pad 143 may have a vertically etched upper portion. For example, referring to FIG. 1, the upper portion of the connection pad 141 and the via pad 143 exposed by an opening part 124 of the solder resist layer 123 may be vertically etched. Here, The connection pad 141 and the via pad 143 may have a vertically etched upper portion having a depth of 0.1 μm or less. The second circuit layer 140 may be formed of copper. However, the kinds of material of the second circuit layer 140 are not limited to copper. That is, the second circuit layer 140 may be formed of any one of conductive materials such as nickel, gold, or the like. In addition, according to the preferred embodiment of the present invention, a seed layer 131 may be formed beneath the second circuit layer 140. The seed layer 131 may be previously formed beneath the second circuit layer 140 so that the second circuit layer 140 is formed to have a predetermined thickness. The seed layer 131 may be formed of a conductive metal, and be formed of the same material as that of the second circuit layer 140.

The solder resist layer 123 may be formed on upper portions of the second circuit layer 140 and the first insulating layer 121. The solder resist layer 123 may include an opening part 124 exposing the upper portion of the connection pad 141 and the via pad 143. That is, the solder resist layer 123 may be formed on the upper portions of the second circuit layer 140 except for the connection pad 141 and the via pad 143 and the first insulating layer 121.

The surface treatment layer 150 may be formed on the upper portion of the connection pad 141 and the via pad 143 exposed by the opening part 124 of the solder resist layer 123. That is, the surface treatment layer 150 may be formed on the upper portion of the connection pad 141 and the via pad 143, which is vertically etched. The surface treatment layer 150 may be formed of an organic solderability preservative (OSP). The OSP may be formed of organic compounds such as imidazoles, benzotriazoles, benzimidazoles, or the like. In addition, the surface treatment layer 150 may be formed of the metal surface treatment layer. The metal surface treatment layer may be formed of at least one of ENEPIG (Electroless nickel-electroless palladium-immersion gold) and ENIG (Electroless nickel-immersion gold).

The solder bump 160 may be formed on the upper portion of the surface treatment layer 150. Although not shown in FIG. 1, an external device such as a semiconductor chip may be mounted on the upper portion of the solder bump 160. In addition, the solder bump 160 may electrically connect the external device to the connection pad 141 and the via pad 143.

Method of Manufacturing Printed Circuit Board

FIGS. 2 to 12 are views sequentially showing a method of manufacturing a printed circuit board according to the preferred embodiments of the present invention.

Referring to FIG. 2, a base substrate 110 is provided.

The base substrate 110 may be formed of a hard material capable of supporting a printed circuit board to be built-up. For example, the base substrate 110 may be formed of a metal plate or an insulating material. Here, the metal plate may be a copper foil, and the insulating material may be a complex polymer resin. Alternatively, the base substrate 110 may easily implement a fine circuit by adopting an Ajinomoto build up film (ABF) or manufacture a printed circuit board to be thin by adopting prepreg. However, the base substrate 110 is not limited thereto, but the base substrate 110 may be formed of a hard insulating material including, an epoxy resin or a modified epoxy resin, a bisphenol A resin, an epoxy-novolak resin, or an aramid reinforced or glass fiber reinforced or paper reinforced epoxy resin.

The base substrate 110 according to the preferred embodiment of the present invention may be a double-sided metallic laminate plate 111 having copper foils formed on both sides of the insulating material. In addition, the base substrate 110 may include a through via 112. The through via 112 may be formed by processing a through-hole in the double-sided metallic laminate plate 111 according to the preferred embodiment of the present invention. When the first circuit layers 113, which are inner circuit layers, are formed on both sides of the base substrate 110, the through via 112 may be formed in order to electrically interconnect the first circuit layers 113. The through via 112 may be formed by being subjected to electroplating. Alternatively, the through via 112 may be formed by being filled with a general conductive paste. In addition, the first circuit layer 113 may be formed of a conductive metal. For example, the first circuit layer 113 may be formed of at least one of gold, silver, nickel, aluminum, copper, and an alloy thereof.

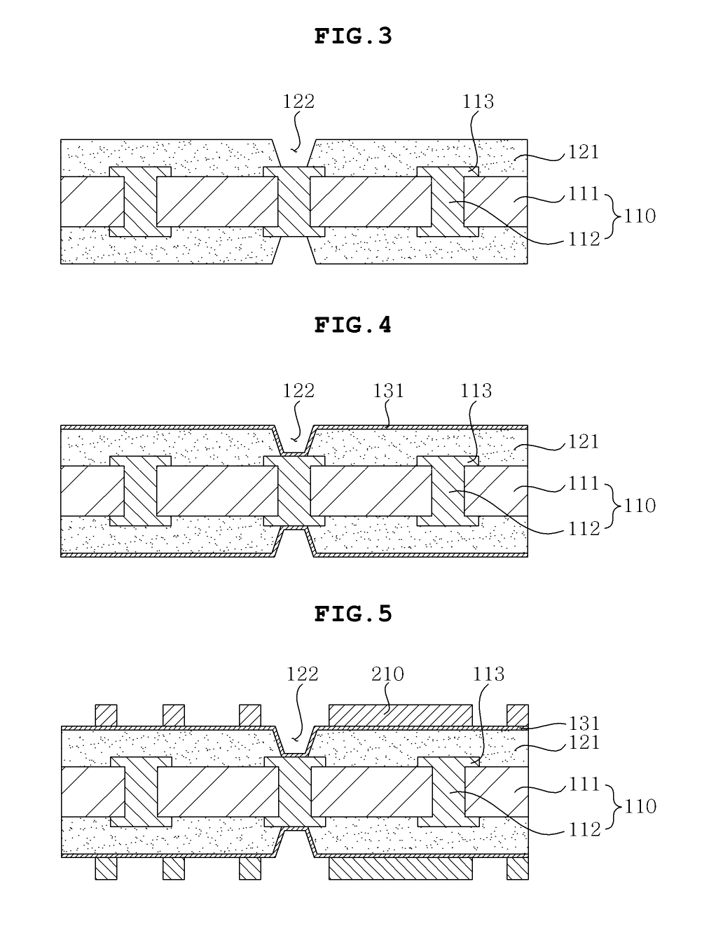

Referring to FIG. 3, a first insulating layer 121 including a via hole 122 may be formed on the upper portion of the base substrate 110. First, the first insulating layer 121 may be formed on the upper portions of the double-sided metallic laminate plate 111 and the through via 112. Here, the first insulating layer 121 may be an insulating layer generally used. That is, as a material of the first circuit layer 121, an epoxy based resin such as FR-4, BT, ABF, or the like may be used. After the first insulating layer 121 is formed on the upper portions of the double-sided metallic laminated plate 111 and the through via 112, the via hole 122 may be formed. The via hole 122 may be formed in the first insulating layer 121 so that a first circuit layer 113 formed on the upper portion of the through via 112 is exposed.

Here, the via hole 122 may be formed through a general etching process and drilling process.

Referring to FIG. 4, after the via hole 122 is formed, a seed layer 131 may be formed on the upper portions of the first insulating layer 121 and the exposed first circuit layer 113. Here, the seed layer 131 may be formed by an electroless plating method.

Referring to FIG. 5, a first plating resist 210 may be formed on the upper portion of the seed layer 131. According to the preferred embodiment of the present invention, the first plating resist 210 may be formed of a dry film. The first plating resist 210 formed on the upper portion of the seed layer 131 may be formed at a predetermined portion except for a portion to be plated for forming a second circuit layer (not shown).

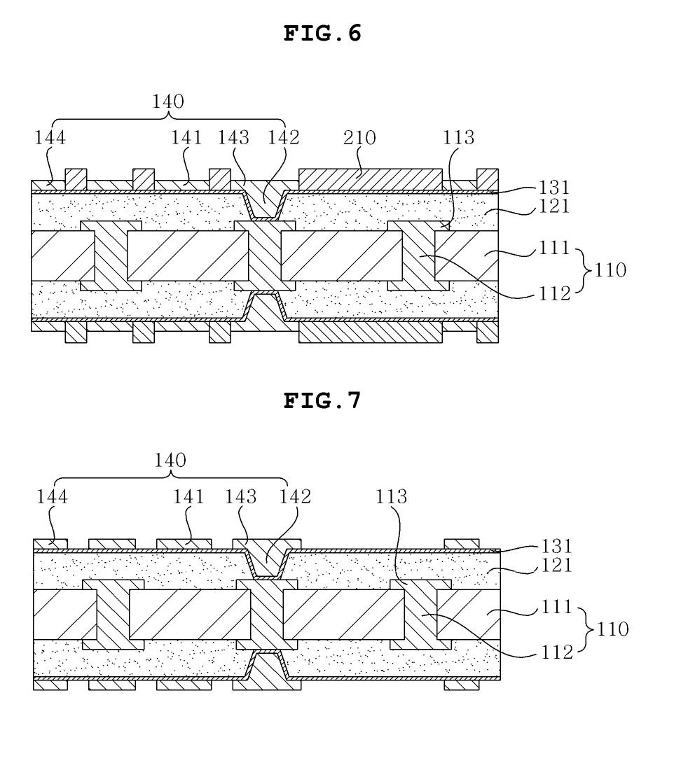

Referring to FIG. 6, a second circuit layer 140 may be formed on the upper portion of the seed layer 131. The second circuit layer 140 may include a connection pad 141, a via 142, a via pad 143, a second circuit pattern 144 or the like. Here, a second circuit pattern 144 is general circuit pattern for electric signal transmission. The connection pad 141 and the via pad 143 may be formed for electrically connecting the second circuit layer 140 and structures formed on the upper portion of the second circuit layer 140. According to the preferred embodiment of the present invention, the via pad 143 may be formed on the upper portion of the via 142. The second circuit layer 140 may be formed to by performing electroplating. As the electroplating is performed, the second circuit layer 140 may be formed on the upper portion of the seed layer 131 in which the first plating resist 210 is not formed. For example, the second circuit layer 140 may be formed of copper. However, the kinds of a material of the second circuit layer 140 are not limited thereto. That is, the second circuit layer 140 may be formed of any one of conductive materials such as nickel, gold, or the like. Here, the via 142 is formed on the first circuit layer 113 electrically connected to the through via 112, such that the through via 112 and the second circuit layer 140 may be electrically connected to each other.

Referring to FIG. 7, the first plating resist 210 formed on the upper portion of the seed layer 131 may be removed. As described above, when the first plating resist 210 is removed, the seed layer 131 may be exposed at a portion at which the first plating resist 210 is removed.

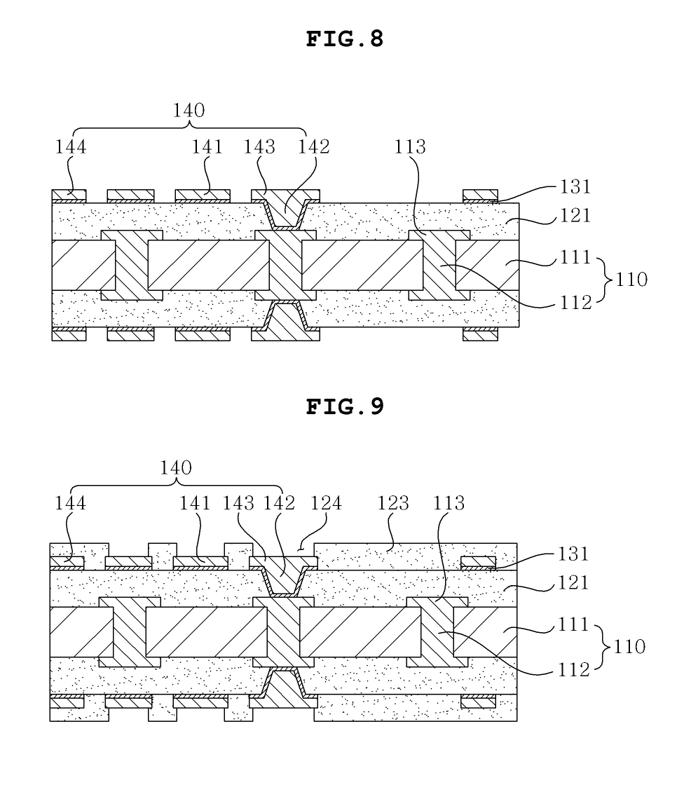

Referring to FIG. 8, after the first plating resist 210 is removed, the seed layer 131 exposed by the removal of the first plating resist 210 may be removed. In this case, the exposed seed layer 131 may be removed by a general flash etching method.

Referring to FIG. 9, the solder resist 123 may be formed on the upper portions of the first insulating layer 121 and the second circuit layer 140.

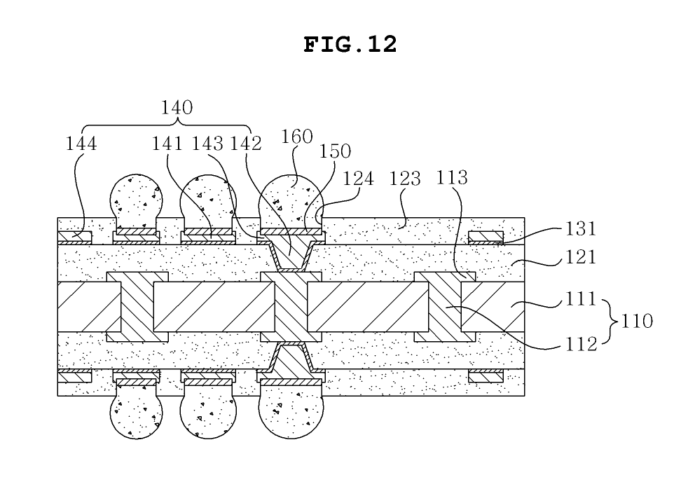

The solder resist layer 123 may include the opening part 124 on which the solder bump 160 (in FIG. 12) to be formed, in order to mount a semiconductor chip, or the like thereon. The connection pad 141 and the via pad 143 of the second circuit layer 140 may be exposed by the opening part 124 formed by the solder resist layer 123. The solder bump 160 (in FIG. 12) for mounting external devices such as a semiconductor chip or the like and electrical interconnection thereof may be formed later on the upper portion of the exposed connection pad 141 and via pad 143. When the solder bump 160 (FIG. 12) is formed, the solder resist layer 123 may be formed in order to protect the second circuit pattern 144. In addition, the solder resist layer 123 is formed on the upper portion of the second circuit to pattern 144, thereby preventing the second circuit pattern 144 from being oxidized.

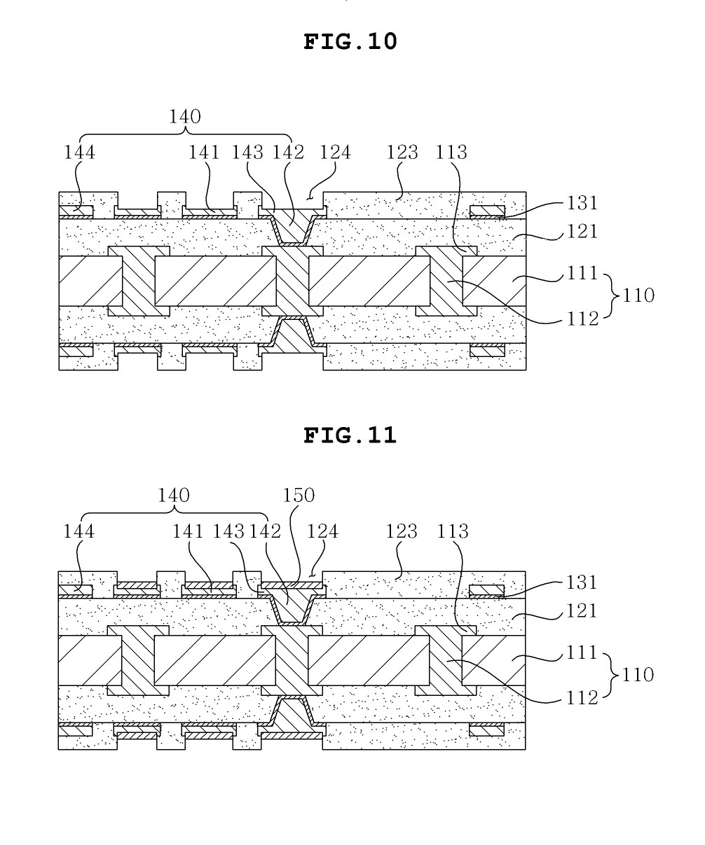

Referring to FIG. 10, a plasma etching process may be performed on the exposed connection pad 141 and via pad 143. The solder resist layer 123 is formed on the upper portion of the second circuit pattern 144, thereby preventing the second circuit layer 140 from being oxidized. However, the connection pad 141 and the via pad 143 of the second circuit layer 140 is exposed to the outside by the opening part 124 of the solder resist layer 123, such that it may be oxidized. That is, a surface oxide film (not shown) may be formed on the upper portion of the connection pad 141 and the via pad 143. In order to remove the surface oxide film (not shown) of the connection pad 141 and the via pad 143, the plasma etching process may be performed on the upper portion of the connection pad 141 and the via pad 143.

The plasma etching process is a process in which reactive gas particles accelerated by electrical energy collide with the surface of the connection pad 141 and the via pad 143 to physically destroy and cut chains of polymer surface molecules. The plasma etching process may be performed in a chamber under a vacuum. The etching extent and roughness of the connection pad 141 and the via pad 143 may be controlled by kinds of the reactive gas, energy density, or the like of the plasma etching process. The reactive gas mainly used in the plasma etching process may be an inert gas and a reductive gas. For example, an inert gas may include helium (He), neon (Ne), krypton (Kr), zenon (Xe), radon (Rn), nitrogen (N), argon (Ar), or the like. In addition, for example, the reductive gas may include hydrogen (H2), methane (CH4), ammonia (NH3), or the like. According to the preferred embodiment of the present invention, the reactive gas used in the plasma etching process may be argon gas, hydrogen gas, or a mixture gas thereof.

The connection pad 141 and the via pad 143 exposed by the opening part 124 of the solder resist layer 123 may be etched by a depth of 0.1 um or less by the plasma etching process. In general, the surface oxide film (not shown) formed on the connection pad 141 and the via pad 143 may be formed to have a depth of 0.1 um or less. Therefore, a surface of the connection pad 141 and the via pad 143 is etched by a depth of 0.1 um or less by the plasma etching process, thereby removing the surface oxide film (not shown).

According to the preferred embodiment of the present invention, although the plasma etching process is performed after the solder resist 123 is formed, a degreasing and washing processes may be additionally performed by those skilled in the art before the plasma etching process is performed.

The degreasing process and the washing process may be a pretreatment process for performing the plasma etching process. The degreasing process is a process for removing pollutants attached to or formed on a surface of the connection pad 141 and the via pad 143 and greasy impurities. After the degreasing process is performed, the washing process may be performed. The washing process is a process for allowing a solution in the previous process attached to a surface of the connection pad 141 and the via pad 143 to be diffused in a short time. The degreasing process and the washing process may be performed by the known technology.

Referring to FIG. 11, a surface treatment layer 150 may be formed on the upper portion of the connection pad 141 and the via pad 143. The surface treatment layer 150 may be formed in order to prevent the exposed the connection pad 141 and the via pad 143 from being oxidized. The surface treatment layer 150 may be formed of organic solderability preservative (OSP). The osp may be formed of organic compounds such as imidazoles, benzotriazoles, benzimidazoles, or the like. The surface treatment layer 150 may be formed by selectively forming the OSP on the upper portion of the connection pad 141 and the via pad 143. The OSP may be formed by coating the organic compound on the upper portion of the connection pad 141 and the via pad 143. Since the OSP, which is the surface treatment layer 150 according to the preferred embodiment of the present invention, may be selectively coated on the connection pad 141 and the via pad 143, it is appropriate for a fine circuit and is environmentally friendly without generating wastewater. In addition, the surface treatment layer 150 may be formed of the metal surface treatment layer. The metal surface treatment layer may be formed of at least one of ENEPIG (Electroless nickel-electroless palladium-immersion gold) and ENIG (Electroless nickel-immersion gold).

According to the preferred embodiment of the present invention, after the surface treatment layer 150 is formed on the upper portion of the connection pad 141 and the via pad 143, the washing process may be further performed. In this case, the washing process may be performed by the known technology. In addition, after the washing process is performed, a drying process may be performed. The drying process is a process for drying a printed circuit board subjected to washing process. The drying process may be performed by the known technology.

Referring to FIG. 12, a solder bump 160 may be formed on the upper portion of the connection pad 141 and the via pad 143. Although not shown in FIG. 12, an external device such as a semiconductor chip may be mounted on the upper portion of the solder bump 160. In addition, the solder bump 160 may electrically connect the external device to the connection pad 141 and the via pad 143.

According to the preferred embodiment of the present invention, the surface oxide film (not shown) of the connection pad 141 and the via pad 143 are removed by the plasma etching process, thereby making it possible to prevent an undercut phenomenon that the via pad 143 is excessively etched, at the time of chemical etching process, which is a wet etching process.

In addition, the undercut phenomenon of the connection pad 141 and the via pad 143 are prevented by the plasma etching process, thereby making it possible to prevent the connection pad 141 and the via pad 143 from being separated from the solder bump 160 that is formed later. Therefore, connection reliability between the connection pad 141 and the via pad 143 and the solder bump 160 may be improved.

In addition, the surface oxide film of the connection pad 141 and the via pad 143 are removed by the plasma etching process, thereby making it possible to reduce pollutions and costs increased due to chemical products at the time of the chemical etching process.

Although the printed circuit board and the method of manufacturing the same according to the preferred embodiment of the present invention have been shown and described in the case in which the printed circuit board is a double-sided printed circuit board having circuit layers formed on both surfaces of a base substrate by way of example, the present invention is not limited thereto. That is, the printed circuit board and the method of manufacturing the same according to the preferred embodiment of the present invention may also be applied to the case in which the printed circuit board is a single-sided printed circuit board having a circuit layer formed on a single surface of the base substrate. In addition, the printed circuit board and the method of manufacturing the same according to the preferred embodiment of the present invention may also be applied to the case in which the printed circuit board is a printed circuit board having a multi-layer structure as well as a printed circuit board having a single layer.

In addition, according to the preferred embodiment of the present invention, although the plasma etching process is applied to the printed circuit board, it may also be applied to all substrates such as Wafer Level Package (WLP) as well as the printed circuit board, or the like, to which a surface treatment is required.

As set forth above, according to the printed circuit board and the method of manufacturing the same according to the preferred embodiment of the present invention, the surface oxide film of the connection pad is removed through the plasma etching process, thereby making it possible to prevent the undercut.

Further, according to the printed circuit board and the method of manufacturing the same according to the preferred embodiment of the present invention, the undercut is prevented at the time of removal of the surface oxide film of the connection pad, thereby making it possible to improve connection reliability between the connection pad and the solder bump.

Further, according to the printed circuit board and the method of manufacturing the same to the preferred embodiment of the present invention, a plurality of unit processes are omitted according to plasma etching processes, thereby making it possible to reduce costs and time.

Although the embodiment of the present invention has been disclosed for illustrative purposes, it will be appreciated that a printed circuit board and a method of manufacturing the same according to the invention are not limited thereby, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board comprising:
a base substrate;
a circuit layer including a connection pad having a vertically etched upper portion and formed on the upper portion of the base substrate;
a solder resist layer formed on the upper portion of the base substrate and including an opening part exposing the connection pad; and
a surface treatment layer formed on the upper portion of the connection pad exposed by the opening part.

2. The printed circuit board as set forth in claim 1, wherein the connection pad has an upper portion exposed by the opening part and vertically etched by a depth of 0.1 um or less.

3. The printed circuit board as set forth in claim 1, wherein the surface treatment layer is formed of an organic solderability preservative (OSP).

4. The printed circuit board as set forth in claim 3, wherein the OSP is formed of at least one of imidazoles, benzotriazoles and benzimidazoles.

5. The printed circuit board as set forth in claim 1, wherein the surface treatment layer is formed of the metal surface treatment layer.

6. The printed circuit board as set forth in claim 5, wherein the metal surface treatment layer is formed of at least one of ENEPIG (Electroless nickel-electroless palladium-immersion gold) and ENIG (Electroless nickel-immersion gold).

7. The printed circuit board as set forth in claim 1, further comprising a solder bump formed on the upper portion of the surface treatment layer.

8. A method of manufacturing a printed circuit board, the method comprising:
preparing a base substrate having a circuit layer formed thereon, the circuit layer including a connection pad exposed to the outside;
performing a plasma etching process on the upper portion of the connection pad; and
forming a surface treatment layer on the upper portion of the connection pad subjected to the plasma etching process.

9. The method as set forth in claim 8, wherein in the performing of the plasma etching process, a reactive gas is an argon (Ar) gas, a hydrogen (H2) gas or a mixture gas of argon and hydrogen.

10. The method as set forth in claim 8, wherein in the performing of the plasma etching process, the connection pad of the base substrate is removed by a depth of 0.1 um or less.

11. The method as set forth in claim 8, wherein in the forming of the surface treatment layer, the surface treatment layer is formed of an OSP.

12. The method as set forth in claim 11, wherein the OSP is formed of at least one of imidazoles, benzotriazoles and benzimidazoles.

13. The method as set forth in claim 8, wherein the surface treatment layer is formed of the metal surface treatment layer.

14. The method as set forth in claim 13, wherein the metal surface treatment layer is formed of at least one of ENEPIG (Electroless nickel-electroless palladium-immersion gold) and ENIG (Electroless nickel-immersion gold).

15. The method as set forth in claim 8, further comprising performing a degreasing process on the base substrate before the performing of the plasma etching process.

16. The method as set forth in claim 8, further comprising performing a washing process on the base substrate after the performing of the degreasing process.

17. The method as set forth in claim 8, further comprising performing a washing process on the base substrate after the forming of the surface treatment layer.

18. The method as set forth in claim 17, further comprising performing a drying process on the base substrate after the performing of the washing process.

19. The method as set forth in claim 8, further comprising forming a solder bump on the upper portion of the surface treatment layer after the forming of the surface treatment layer.
